(19) United States
(12) Patent Application Publication
(10) Pub. No.: US 2021/0233975 A1
(43) Pub. Date: Jul. 29, 2021

(54) DEVICE COMPRISING AN IMAGE SENSOR AND A DISPLAY SCREEN

(71) Applicant: ISORG, Limoges CEDEX 3 (FR)

(72) Inventors: Benjamin BOUTHINON, GRENOBLE (FR); Emeline SARACCO, GRENOBLE (FR); Jérôme JOIMEL, GRENOBLE (FR)

(21) Appl. No.: 15/734,930

(22) PCT Filed: Jun. 3, 2019
(86) PCT No.: PCT/FR2019/051306

§ 371 Date: Dec. 3, 2020

(30) Foreign Application Priority Data
Jun. 4, 2018 (FR) 18/70644

(51) Int. Cl. H01L 27/32

(52) U.S. Cl. CPC H01L 27/3234; H01L 27/3258; H01L 27/322; H01L 27/3227

(57) ABSTRACT

An optoelectronic device includes a display screen and an image sensor. The display screen includes a matrix of organic light-emitting components connected to first transistors and the image sensor includes a matrix of organic photodetectors connected to second transistors. The resolution of the optoelectronic device for the light-emitting components is greater than 300 ppi and the resolution of the optoelectronic device for the photodetectors is greater than 300 ppi. The total thickness of the optoelectronic device is less than 2 mm.

The present patent application claims the priority of French patent application FR18/70644, which is incorporated herein by reference.

### FIELD

The present disclosure relates generally to optoelectronic devices, and more particularly to devices comprising a display screen and an image sensor.

### BACKGROUND OF THE INVENTION

Many computers, touch-sensitive tablets, mobile telephones, smartwatches, are equipped with a touch-sensitive or non-touch-sensitive display screen and a camera. There are also many devices of this type which are equipped with a fingerprint sensor. This fingerprint sensor is generally positioned outside the surface occupied by the display screen.

More recently, printed image sensors have appeared, which may be used at the periphery of, or even below a display screen. This image sensor technology is described, for example, in documents FR-A-2996933, US-20150293661 (B12003).

The appearance of this technology has opened the door for the integration, into an electronic device, of a fingerprint sensor made in the form of an image sensor, below a display screen.

It would be desirable to improve the production of such a device integrating an image sensor and a display screen.

### SUMMARY

One object of one embodiment is to address all or some of the drawbacks of the known electronic devices comprising a display screen and an image sensor.

Another object of one embodiment is for the image sensor to be made at least in part with organic semiconductor materials.

Another object of one embodiment is to provide an optoelectronic device comprising a display screen and an image sensor that is easier to produce than the known display systems.

Another object is to reduce the thickness of the optoelectronic device.

Another object of one embodiment is to produce a touch-sensitive surface comprising a display screen and an image sensor.

Another object of one embodiment is for all or part of the optoelectronic device to be able to be made through successive depositions of layers using printing techniques, for example by inkjet, heliography, screen printing, flexography or coating.

Thus, one embodiment provides an optoelectronic device comprising a display screen and an image sensor, the display screen comprising a matrix of organic light-emitting components connected to first transistors, the image sensor comprising a matrix of organic photodetectors connected to second transistors, the resolution of the optoelectronic device for the light-emitting components being greater than 300 ppi and the resolution of the optoelectronic device for the photodetectors being greater than 300 ppi, the total thickness of the optoelectronic device being less than 2 mm.

According to one embodiment, the first and second transistors comprise semiconductor regions in contact with a first electrically insulating layer.

According to one embodiment, the device comprises a second electrically insulating layer, all of the first electrodes being in contact with the second electrically insulating layer.

According to one embodiment, the device comprises a second electrode which is attached to all of the light-emitting components and/or to all of the photodetectors.

According to one embodiment, the second electrode is in contact with all of the light-emitting components and with all of the photodetectors.

According to one embodiment, the device comprises a substrate and a stack of layers covering the substrate and containing all of the light-emitting components and the photodetectors, and the photodetectors are located between the light-emitting components and the substrate or the light-emitting components are located between the photodetectors and the substrate.

According to one embodiment, the photodetectors comprise at least one electrically conductive or semiconductive layer shared by all of the photodetectors and comprising openings, the light-emitting components being connected to the first transistors by electrically conductive elements extending through the openings.

According to one embodiment, the second electrode is attached to all of the light-emitting components and comprises openings, the photodetectors being connected to the second transistors by electrically conductive elements extending through the openings.

According to one embodiment, at least one of the photodetectors covers more than one light-emitting component.

According to one embodiment, each photodetector covers a single light-emitting component.

According to one embodiment, the electrically conductive or semi-conductive layer is attached to the second electrode.

According to one embodiment, the device further comprises first colored filters covering the photodetectors.

According to one embodiment, the device further comprises second colored filters covering the light-emitting components.

According to one embodiment, the device further comprises a layer which is opaque to the radiation detected by the photodetectors extending between the first and second filters.

According to one embodiment, the device further comprises an angular filter, covering each photodetector, and which is suitable for blocking rays of said radiation whose incidence relative to a direction orthogonal to a face of the optoelectronic device is above a threshold and for allowing rays of said radiation to pass whose incidence relative to a direction orthogonal to the face is below the threshold.

According to one embodiment, each light-emitting component comprises a first active region which is the region from which the majority of the radiation emitted by the light-emitting component is emitted, and each photodetector comprises a second active region which is the region from which the majority of the radiation detected by the photodetector is detected.

According to one embodiment, the first and second transistors are field-effect transistors comprising gates, the optoelectronic device further comprising first conductive tracks attached to the gates of the first transistors and second conductive tracks attached to the gates of the second transistors and at least one of the first conductive tracks is also attached to the gate of one of the second transistors.

According to one embodiment, the light-emitting components comprise at least first light-emitting components which are suitable for emitting first radiation and second light-emitting components which are suitable for emitting second radiation, and the first conductive tracks attached to the gates of the first transistors connected to the first light-emitting components are also attached to the gates of the second transistors connected to the photodetectors adjacent to the first light-emitting components.

According to one embodiment, the device further comprises an infrared filter covering the photodetectors.

One embodiment also provides for using the optoelectronic device as previously defined to detect at least one fingerprint of a user.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 is a partial schematic sectional view of one embodiment of an optoelectronic device comprising an image sensor and a display screen;

FIG. 2 is another partial and schematic sectional view of the embodiment of FIG. 1;

FIG. 3 is a partial and schematic sectional view, similar to FIG. 2, illustrating another arrangement of the display screen and of the image sensor;

FIG. 4 is a partial schematic sectional view of another embodiment of an optoelectronic device comprising an image sensor and a display screen;

FIG. 5 is a partial schematic top view of the optoelectronic device shown in FIG. 4;

FIG. 6 is another partial schematic top view of the optoelectronic device shown in FIG. 4.

FIG. 7 is a partial schematic sectional view of another embodiment of an optoelectronic device comprising an image sensor and a display screen;

FIG. 8 is a partial schematic sectional view of another embodiment of an optoelectronic device comprising an image sensor and a display screen;

FIG. 9 is a partial schematic sectional view of another embodiment of an optoelectronic device comprising an image sensor and a display screen;

FIG. 10 is a partial schematic sectional view of another embodiment of an optoelectronic device comprising an image sensor and a display screen;

FIG. 11 is a partial schematic sectional view of another embodiment of an optoelectronic device comprising an image sensor and a display screen;

FIG. 12 is a partial schematic sectional view of an embodiment of an angular filter of an optoelectronic device shown in FIG. 11;

FIG. 13 is a partial schematic top view of an embodiment of an angular filter of an optoelectronic device shown in FIG. 11; and

FIG. 14 is a partial schematic sectional view of another embodiment of an optoelectronic device comprising an image sensor and a display screen.

### DETAILED DESCRIPTION OF THE INVENTION

Like features have been designated by like references in the various figures. For the sake of clarity, only the operations and elements that are useful for an understanding of the embodiments which will be described herein have been illustrated and will be described in detail. In particular, the operation of the display screen and of the image sensor has not been outlined, the described embodiments being compatible with the usual screens and sensors. Furthermore, the other components of the electronic device integrating a display screen and an image sensor have also not been outlined, the described embodiments being compatible with the other usual components of electronic devices with display screen.

Unless indicated otherwise, when reference is made to two elements attached together, this signifies a direct attachment without any intermediate element other than conductors, and when reference is made to two elements connected or coupled together, this signifies that these two elements can be directly connected or they can be connected via one or more other elements.

In the description that follows, the expressions “in the order of” and “substantially” signify within 10%, and preferably within 5%.

Furthermore, unless indicated otherwise, when reference is made to absolute positional qualifiers, such as the terms “top”, “bottom”, etc., or to relative positional qualifiers, such as the terms “above”, “below”, “higher”, “lower”, etc., reference is made to the orientation shown in the figures.

A pixel of an image corresponds to the unitary element of the image displayed by the display screen. When the display screen is a color image display screen, it generally comprises, in order to display each pixel of the image, at least three components for emitting and/or regulating the light intensity, also called display subpixels, which each emit light radiation substantially in a single color (for example, red, green and blue). The superposition of the rays emitted by these three display subpixels provides the viewer with the colored sensation corresponding to the pixel of the displayed image. In this case, the assembly formed by the three display subpixels used to display a pixel of an image is referred to as display pixel of the display screen. When the display screen is a monochrome image display screen, it generally comprises a single light source in order to display each pixel of the image.

The active region of an optoelectronic component, in particular a light-emitting component of a display subpixel or a photodetector, refers to the region from which the majority of the electromagnetic radiation supplied by the optoelectronic component is emitted or the region from which the majority of the electromagnetic radiation received by the optoelectronic component is detected. In the remainder of the disclosure, an optoelectronic comported is said to be organic when the majority, preferably all, of the active region of the optoelectronic component is made from at least one organic material or from a mixture of organic materials.

Another embodiment provides an optoelectronic device comprising a display screen and an image sensor. The display screen comprises a matrix of display subpixels each comprising an organic light-emitting component and the image sensor comprises a matrix of organic photodetectors. According to one embodiment, the active regions of the light-emitting components of the display subpixels are formed substantially in the same plane as the active regions of the photodetectors. According to one embodiment, the light-emitting components and the photodetectors have a common electrode.

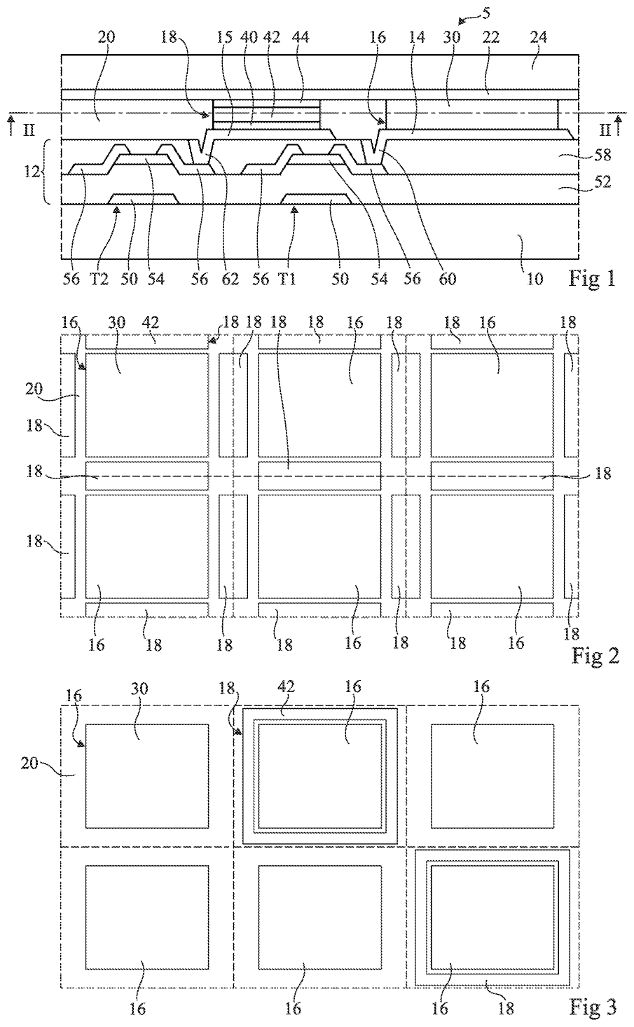

FIGS. 1 and 2 are respectively a side sectional view and a sectional top view, both partial and schematic, of one embodiment of an optoelectronic device 5 comprising an image sensor and a display screen. FIG. 2 is a sectional view of FIG. 1 along line II-II.

The device 5 comprises, from bottom to top in FIG. 1:

a substrate 10;

a stack 12 in which thin-film transistors T1 and T2 are formed;

electrodes 14, 15, each electrode 14 being connected to one of the transistors T1 and each electrode 15 being connected to one of the transistors T2;

light-emitting components 16, for example organic light-emitting diodes 16, also called OLED, each light-emitting component 16 being in contact with one of the electrodes 14 and photodetectors 18, for example organic photodiodes 18, also called OPD, each photodetector 18 being in contact with one of the electrodes 15, the organic light-emitting diodes 16 and the organic photodiodes 18 being laterally separated by an electrically insulating layer 20;

an electrode 22 in contact with all of the organic light-emitting diodes 16 and all of the organic photodiodes 18; and

a coating 24.

Preferably, the resolution of the optoelectronic device for the light-emitting components 16 is greater than 300 ppi and the resolution of the optoelectronic device for the photodetectors 18 is greater than 300 ppi. Preferably, the total thickness of the optoelectronic device is less than 2 mm.

According to one embodiment, each organic light-emitting diode 16 comprises an active region 30, the electrodes 14 and 22 being in contact with the active region 30.

According to one embodiment, each organic photodiode 18 comprises, from bottom to top in FIG. 1:

a first interface layer 40 in contact with one of the electrodes 15;

an active region 42 in contact with the first interface layer 40; and

a second interface layer 44 in contact with the active region 42, the electrode 22 being in contact with the second interface layer 44.

According to the embodiment, the stack 12 comprises:

electrically conductive tracks 50 resting on the substrate 10 and forming the gate conductors of the transistors T1 and T2;

a layer 52 of a dielectric material covering the gate conductors 50 and the substrate 10 between the gate conductors 50 and forming the gate insulators of the transistors T1 and T2;

active regions 54 resting on the dielectric layer 52 opposite gate conductors 50;

electrically conductive tracks 56 in contact with active regions 54 and forming the drain and source contacts of the transistors T1 and T2; and

a layer 58 of a dielectric material covering the active regions 54 and the electrically conductive tracks 56, the electrodes 14 resting on the layer 58 and being attached to some of the conductive tracks 56 by conductive vias 60 passing through the insulating layer 58 and the electrodes 15 resting on the layer 58 and being attached to some of the conductive tracks 56 by conductive vias 62 passing through the insulating layer 58.

As a variant, the transistors T1 and T2 can be of the top-gate type.

The interface layer 40 or 44 can correspond to an electron injection layer or to a hole injection layer. The output work of the interface layer 40 or 44 is suitable for blocking, collection or injecting holes and/or electrons depending on whether this interface layer acts as a cathode or an anode. More specifically, when the interface layer 40 or 44 acts as an anode, it corresponds to a hole injection and electron blocking layer. The output work of the interface layer 40 or 44 is then greater than or equal to 4.5 eV, preferably greater than or equal to 5 eV. When the interface layer 40 or 44 acts as a cathode, it corresponds to an electron injection and hole blocking layer. The output work of the interface layer 40 or 44 is then less than or equal to 4.5 eV, preferably less than or equal to 4.2 eV.

According to one embodiment, the electrode 14 or 22 advantageously directly serves as electron injection layer or hole injection layer for the light-emitting diode 16 and it is not necessary to provide, for the light-emitting diode 16, an interface layer sandwiching the active region 30 and acting as electron injection layer or hole injection layer. According to another embodiment, interface layers acting as electron injection layer or hole injection layer can be provided between the active region 30 and the electrodes 14, 15, 22.

The substrate 10 can be a rigid substrate or a flexible substrate. The substrate 10 can have a monolayer structure or correspond to a stack of at least two layers. An example of a rigid substrate comprises a substrate made of silicon, germanium or glass. Preferably, the substrate 10 is a flexible film. An example of flexible substrate comprises a film made of PEN (polyethylene naphthalate), PET (polyethylene terephthalate), PI (polyimide), CTA (cellulose triacetate), COP (cyclo-olefin copolymer) or PEEK (polyether ether ketone). The thickness of the substrate 10 can be between 5 μm and 1000 μm. According to one embodiment, the substrate 10 can have a thickness from 10 μm to 300 μm, preferably between 75 μm and 250 μm, in particular in the order of 125 μm, and have a flexible behavior, that is to say that the substrate 10 can, under the action of an outside force, deform, in particular bend, without breaking or tearing. The substrate 10 can comprise at least one layer which is substantially tight with respect to oxygen and moisture so as to protect the organic layers of the device 5. It may involve one or more layers deposited by an atomic layer deposition (ALD) method, for example a layer made of Al₂O₃.

According to one embodiment, the material making up the electrodes 14, 15 and the electrode 22 is chosen from the group comprising:

a transparent conductive oxide (TCO), in particular ITO, an aluminum zinc oxide (AZO), a gallium zinc oxide (GZO), an ITO/Ag/ITO alloy, an ITO/Mo/ITO alloy, an AZO/Ag/AZO alloy or a ZnO/Ag/ZnO alloy;

a metal or a metal alloy, for example silver (Ag), gold (Au), lead (Pb), palladium (Pd), copper (Cu), nickel (Ni), tungsten (W), molybdenum (Mo), aluminum (Al), chromium (Cr) or an alloy of magnesium and silver (MgAg);

carbon, silver and gold nanowires;

graphene; and

a mixture of at least two of these materials.

Preferably, the electrode 22 is made of MgAg, the electrode 14 is made of Al and the electrode 15 is made of ITO or ITO/Mo/ITO.

When the radiation emitted by the display screen escapes from the optoelectronic device 5 through the coating 24, the electrode 22 and the coating 24 are at least partially transparent to the electromagnetic radiation emitted by the organic light-emitting diodes 16 and to the electromagnetic radiation detected by the organic photodiodes 18. The electrode 22 is for example made of MgAg. The electrode 22 is then preferably semitransparent, for example at about 50%, to perform the role of optical cavity so as to maximize light emission. The electrodes 14, 15 and the substrate 10 can then be opaque to the electromagnetic radiation emitted by the organic light-emitting diodes 16 and to the electromagnetic radiation detected by the organic photodiodes 18. When the radiation emitted by the display screen escapes from the optoelectronic device 5 through the substrate 10, the electrodes 14, 15 and the substrate 10 are materials which are at least partially transparent to the electromagnetic radiation emitted by the organic light-emitting diodes 16 and to the electromagnetic radiation detected by the organic photodiodes 18. The electrodes 14, 15 are for example made of TCO. The electrode 22 can then be opaque to the electromagnetic radiation emitted by the organic light-emitting diodes 16 and to the electromagnetic radiation detected by the organic photodiodes 18.

The insulating layer 20 can have a monolayer or multilayer structure and comprise at least one layer made of silicon nitride (SiN), silicon oxide (SiO₂) or a polymer, in particular a resin. The insulating layer 20 can correspond to a stack of inorganic layers, in particular made of SiN or SiO₂ and at least one layer made of a polymer.

The coating 24 is transparent or partially transparent to visible light. The coating 24 is preferably substantially tight with respect to air and water. The material making up the coating 24 is chosen from the group comprising a polyepoxide or a polyacrylate. Among the polyepoxides, the material making up the coating 24 can be chosen from the group comprising bisphenol A epoxy resins, in particular bisphenol A diglycidyl ether (BADGE) and bisphenol A and tetrabromobisphenol A diglycidyl ethers, bisphenol F epoxy resins, epoxidized novolac resins (ENR), in particular epoxy phenol novolac(EPN) resins and epoxy cresol novolac (ECN) resins, aliphatic epoxy resins, glycidyl group epoxy resins and cycloaliphatic epoxides, glycidyl amine epoxy resins, in particular tetraglycidyl methylene dianiline (TGMDA) ethers, and a mixture of at least two of these compounds. Among the polyacrylates, the material composing the coating 24 can be made from monomers comprising acrylic acid, methylmethacrylate, acrylonitrile, methacrylates, methyl acrylate, ethyl acrylate, 2-chloroethyl vinyl ether, 2-ethylhexyl acrylate, hydroxyethyl(methacrylate), butyl acrylate, butyl methacrylate, trimethylolpropane triacrylate (TMPTA) and derivatives of these products. The coating 24 can comprise at least one layer of SiN, for example deposited by plasma-enhanced chemical vapor deposition (PECVD), and/or a layer of aluminum oxide (Al₂O₃), for example deposited by ALD. The coating 24 can comprise a multilayer structure comprising an organic layer between two layers of SiN, the organic layer acting as moisture absorption layer.

When the coating 24 comprises at least one polyepoxide or a polyacrylate, the thickness of the coating 24 is between 1 μm and 50 μm, preferably between 5 μm and 40 μm, in particular in the order of 15 μm. When the coating 24 comprises a layer of SiN, the thickness of the coating 24 is between 100 nm and 300 nm. When the coating 24 comprises a layer of Al₂O₃, the thickness of the coating 24 is between 1 nm and 50 nm.

The active region 30 of the light-emitting diode 16 is for example made of a light-emitting material. The light-emitting material can be a polymeric light-emitting material, as described in the publication titled “Progress with Light-Emitting Polymers” by M. T. Bernius, M. Inbasekaran, J. O'Brien and W. Wu (Advanced Materials, 2000, Volume 12, Issue 23, pages 1737-1750) or a light-emitting material with low molecular weight such as aluminum trisquinoline, as described in U.S. Pat. No. 5,294,869. The light-emitting material can comprise a mixture of a light-emitting material and a fluorescent dye or can comprise a layered structure of a light-emitting material and a fluorescent dye. The light-emitting polymers comprise polyfluorene, polybenzothiazole, polytriarylamine, polyphenylene vinylene and polythophene. The preferred light-emitting polymers comprise the homopolymers and copolymers of 9,9-di-n-octylfluorene (F8), N, N-bis (phenyl)-4-sec-butylphenylamine (TFB), benzothiadiazole (BT) and 4,4′-N,N′-dicarbazole-biphenyl (CBP) doped with tris(2-phenylpyridine) iridium (Ir(ppy)3). The thickness of the active region 30 is between 1 nm and 100 nm.

In the case where the interface layer 40 or 44 acts as an electron injection layer, the material composing the interface layer 40 or 44 is chosen from the group comprising:

a metal oxide, in particular a titanium oxide or a zinc oxide;

a molecular host/dopant system, in particular the products marketed by the company Novaled under the names NET-5/NDN-1 or NET-8/MDN-26;

a doped conductive or semiconductive polymer, for example the PEDOT:Tosylate polymer, which is a mixture of poly(3,4)-ethylenedioxythiophene and tosylate;

a carbonate, for example CsCO₃;

a polyelectrolyte, for example poly[9,9-bis(3′-(N,N-dimethylamino)propyl)-2,7-fluorene-alt-2,7-(9,9-dioctyfluorene)] (PFN), poly[3-(6-trimethylammoniumhexyl) thiophene] (P3TMAHT) or poly[9,9-bis(2-ethylhexyl) fluorene]-b-poly[3-(6-trimethylammoniumhexyl] thiophene (PF2/6-b-P3TMAHT);

a polyethyleneimine (PEI) polymer or an ethoxylated (PEIE), propoxylated and/or butoxylated polyethyleneimine polymer;

MgAg;

tris(8-hydroxyquinoleine)aluminium(III) (Alq₃);

2-(4-Biphenylyl)-5-(4-tert-butylphenyl)-1,3,4-oxadiazole (Bu-PBD); and

a mixture of two or more of these materials.

Preferably, the lower interface layer 40 acts as an electron injection layer and is made from an ethoxylated polyethyleneimine polymer.

In the case where the interface layer 40 or 44 acts as a hole injection layer, the material composing the interface layer 40 or 44 can be chosen from the group comprising:

a doped conductive or semiconductive polymer, in particular the materials marketed under the names Plexcore OC RG-1100, Plexcore OC RG-1200 by the company Sigma-Aldrich, the polymer PEDOT:PSS, which is a mixture of poly(3,4)-ethylenedioxythiophene and sodium polystyrene sulfonate, or a polyaniline;

a molecular host/dopant system, in particular the products marketed by the company Novaled under the names NHT-5/NDP-2 or NHT-18/NDP-9;

a polyelectrolyte, for example Nafion;

a metal oxide, in particular a molybdenum oxide, a vanadium oxide, ITO, or a nickel oxide;

Bis[(1-naphthyl)-N-phenyl]benzidine (NPB);

triarylamines (TPD); and

a mixture of two or more of these materials.

Preferably, in the case where the interface layer 40 or 44 acts as a hole injection layer, the material composing the interface layer 40 or 44 is a doped conductive or semiconductive polymer.

Preferably, the upper interface layer 44 acts as hole injection layer and is made of PEDOT:PSS. One advantage of PEDOT:PSS is that it can be deposited easily using printing techniques, for example by inkjet, heliography, screen printing or coating.

The thickness of the lower interface layer 40 is between a monolayer and 10 μm, preferably between a monolayer and 60 nm, in particular in the order of 10 nm. The thickness of the upper interface layer 44 covering the active region 42 is between 10 nm and 20 μm, preferably between 50 nm and 500 nm, in particular in the order of 100 nm.

The active region 42 comprises at least one organic material and can comprise a stack or a mixture of several organic materials. The active region 42 can comprise a mixture of an electron donor polymer and an electron acceptor molecule. The functional zone of the active region 42 is delimited by the overlap between the lower interface layer 40 and the upper interface layer 44. The currents passing through the functional zone of the active region 42 can vary from several femtoamperes to several microamperes. The thickness of the active region 42 covering the lower interface layer 40 can be between 50 nm and 5 μm, preferably between 300 nm and 2 μm, for example in the order of 500 nm.

The active region 42 can comprise small molecules, oligomers or polymers. It can involve organic or inorganic materials. The active region 42 can comprise an ambipolar semiconductor material, or a mixture of an N semiconductor material and a P semiconductor material, for example in the form of superimposed layers or a close mixture on the nanometric scale so as to form a volume heterojunction.

Examples of the semiconductor polymers suitable for producing the active region 42 are poly(3-hexylthiophene) (P3HT), poly[N-9′-heptadecanyl-2,7-carbazole-alt-5,5-(4,7-di-2-thienyl-2′,1′,3′-benzothiadiazole)] (PCDTBT), Poly[(4,8-bis-(2-ethylhexyloxy)-benzo[1,2-b;4,5-b′]dithiophene)-2,6-diyl-alt-(4-(2-ethylhexanoyl)-thie-no[3,4-b]thiophene))-2,6-diyl];4,5-b′]dithi-ophene)-2,6-diyl-alt-(5,5′-bis(2-thienyl)-4,4,-dinonyl-2,2′-bithiazole)-5′,5″-diyl] (PBDTTT-C), poly[2-methoxy-5-(2-ethyl-hexyloxy)-1,4-phenylene-vinylene] (MEH-PPV) or Poly[2,6-(4,4-bis-(2-ethylhexyl)-4H-cyclopenta [2,1-b;3,4-b′]dithiophene)-alt-4,7(2,1,3-benzothiadiazole)] (PCPDTBT).

Examples of N-type semiconductor materials suitable for producing the active region 42 are fullerenes, in particular C60, [6,6]-phenyl-C61-butanoate methyl ([60]PCBM), [6,6]-phenyl-C71-butanoate methyl ([70]PCBM), perylene diimide, zinc oxide (ZnO) or nanocrystals allowing the formation of quantum dots or small molecules.

The thickness of the stack comprising the lower interface layer 40, the active region 42 and the upper interface layer 44 is between 500 nm and 4 μm, preferably between 500 nm and 1 μm.

The conductive tracks 50, 56 can be made of the same material as the electrodes 14, 15 and/or 22.

The active regions 54 can be made of polycrystalline silicon, in particular from low-temperature polycrystalline silicon (LTPS), amorphous silicon (aSi), indium-gallium-zinc oxide (IGZO), polymer, or comprise small molecules used in known manner to produce organic thin film transistors (OTFT).

According to one embodiment, the active regions 54 of the transistors T1 and T2 can be made from different materials. As an example, the active region 54 of the transistor T2 connected to the photodiode can be made of IGZO or aSi and the active region 54 of the transistor T1 connected to the light-emitting diode can be made of LTPS.

The insulating layer 52 can be made of SiN, SiO2 or organic polymer. The insulating layer 52 can have a thickness between 10 nm and 4 μm.

The insulating layer 52 can be made of SiN, SiO2 or organic polymer. The insulating layer 52 can have a thickness between 10 nm and 4 μm.

The insulating layer 58 can be made of SiN, SiO2 or organic polymer. The insulating layer 58 can have a thickness between 10 nm and 4 μm.

The device 5 can further comprise a polarizing filter, positioned for example on the coating 24. The device 5 can further comprise color filters opposite the photodetectors 18 in order to obtain a wavelength selection of the radiation reaching the photodetectors 18.

As visible in FIG. 2, the light-emitting diodes 16 and the photodetectors 18 are arranged in rows and columns, light-emitting diodes 16 being positioned so as to alternate with the photodetectors 18.

In the present embodiment, in the section of FIG. 2, each active region 30 of the light-emitting diode 16 is shown with a square shape and each active region 42 of a photodiode 18 is shown with a rectangular shape. However, it is clear that the shape of the active regions 30, 42 can be different, for example polygonal. In the section plane of FIG. 2, the surface occupied by the active region 42 of a photodiode 18 is less than the surface of the active region 30 of a light-emitting diode 16. However, it is clear that the surfaces of the active regions 30 of the light-emitting diodes 16 and of the active regions 42 of the photodiodes 18 depend on the targeted applications.

According to one embodiment, the device 5 is suitable for detecting the position of an actuating member, not shown, relative to the matrix of photodetectors 18. In particular, the device 5 can be suitable for detecting movements of the actuating member in a plane parallel to the plane of the matrix of photodetectors 18, and variations of the distance Z between the actuating member and the matrix of photodetectors 18.

According to one embodiment, the device 5 is suitable for detecting variations in the shadow cast by the actuating member on the matrix of sensors, when the actuating member is positioned between the light source and the matrix and for deducing information therefrom which is representative of a position variation of the actuating member. The light source is preferably the ambient light, for example the sun or the indoor electric light in a room of a building.

According to another embodiment, the device 5 further comprises a source of radiation able to be returned, at least in part, by the actuating member. The device 5 is suitable for detecting the radiation returned onto the matrix of photodetectors and for deducing information therefrom which is representative of a position variation of the actuating member. This is for example visible or infrared radiation. In this case, the reflection/diffusion of the visible or infrared radiation on the actuating member, seen by the photon sensors, is preferably used to obtain information relative to the position of the actuating member.

The display subpixels can be distributed into first display subpixels suitable for emitting radiation at a first wavelength, into second display subpixels suitable for emitting radiation at a second wavelength and into third display subpixels suitable for emitting radiation at a third wavelength. According to one embodiment, the light-emitting diodes of the first, second and third display subpixels are suitable for emitting radiation respectively at the first, second and third wavelengths. According to another embodiment, the light-emitting diodes of the first, second and third display subpixels are suitable for emitting radiation at a fourth wavelength and the first, second and third display subpixels comprise photoluminescent blocks which are suitable for converting the radiation at the fourth wavelength into radiation respectively at the first, second and third wavelengths. According to one embodiment, the first wavelength corresponds to blue light and is in the range from 440 nm to 490 nm. According to one embodiment, the second wavelength corresponds to green light and is in the range from 510 nm to 570 nm. According to one embodiment, the third wavelength corresponds to red light and is in the range from 600 nm to 720 nm.

FIG. 3 is a view similar to FIG. 2 of another arrangement of the photodiodes 18 in which the photodiodes 18 are provided only nearby, for example around some of the display subpixels. According to one embodiment, the photodiodes 18 can be configured to detect the radiation reflected by an actuating member, for example the finger of a user. According to one embodiment, the image sensor can be used to detect a fingerprint of a user. It may be advantageous, in particular for the implementation of processing algorithms of the images acquired by the image sensor, for the latter to be configured to acquire an image preferentially in a preferred range of wavelengths, for example the green. In this case, the photodetectors 18 are preferably located only around active regions 30 of the display subpixels emitting light in the preferred wavelength range, for example the display subpixels emitting green light.

Depending on the considered materials, the method for forming layers of the image sensor and of the display screen can correspond to a so-called additive method, for example by direct printing of the material making up the organic layers in the desired locations in particular in the form of sol-gel, for example by printing by inkjet, heliography, screen printing, flexography, spray coating or drop-casting. According to the considered materials, the method for forming layers of the image sensor and of the display screen can correspond to a so-called subtractive method, in which the material making up the organic layers is deposited on the entire structure and in which the unused portions are next removed, for example by photolithography or by laser ablation. Depending on the considered material, the deposition on the entire structure may be done for example by liquid route, by cathode sputtering or by evaporation. This may in particular involve methods such as spin coating, spray coating, heliography, slot-die coating, blade-coating, flexography or screen printing. When the layers are made from metal, the metal is for example deposited by evaporation or by cathode sputtering on the entire support and the metal layers are delimited by etching.

Advantageously, at least some of the layers of the image sensor and/or of the display screen can be made using printing techniques. The materials of these layers previously described can be deposited in liquid form, for example in the form of conductive and semiconductive inks using inkjet printers. Here, “materials in liquid form” also refer to materials in gel form which can be deposited by printing techniques. Annealing steps are optionally provided between the deposits of the different layers, but the annealing temperatures cannot exceed 150° C., and the deposition and any annealing operations can be done at atmospheric pressure.

According to one embodiment, the conductive tracks 50 for controlling the gates of the transistors T1 are separate from the conductive tracks 50 for controlling the gates of the transistors T2. According to one embodiment, the conductive tracks 50 for controlling the gates of at least a portion of the transistors T2 are shared with the conductive tracks 50 for controlling the gates of at least a portion of the transistors T1. This advantageously makes it possible to reduce the space requirement of the optoelectronic device. As an example, when the optoelectronic device comprises several types of display subpixels which each emit a light radiation substantially in a single color (for example red, green and blue), the conductive tracks 50 for controlling the gates of the transistors T1 connected to the light-emitting diodes 16 emitting in at least one of these colors can be combined with the conductive tracks 50 for controlling the gates of the transistors T2 connected to the photodetectors 18 adjacent to these light-emitting diodes 16. In this case, the reading of the signals detected by the photodetectors 18 is simultaneous with the activation of the light-emitting diodes 16.

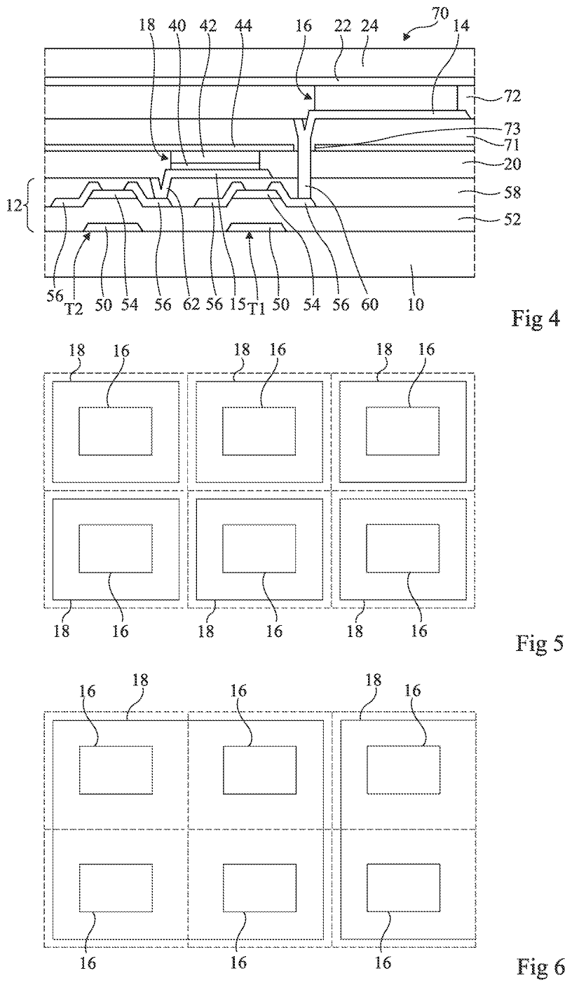

FIG. 4 is a schematic sectional view of one embodiment of an optoelectronic device 70. The optoelectronic device 70 comprises all of the elements of the optoelectronic device 5 previously described, except that the photodetectors 18 and the light-emitting diodes 16 are made on two different levels of the stack of layers covering the substrate 10. In the present embodiment, in the set of layers covering the substrate 10, the photodetectors 18 are formed between the stack 12 of layers in which the transistors T1, T2 are formed and the level where the light-emitting diodes 16 are formed. In particular, the photodetectors 18 can cover the transistors T1, T2 in the stacking direction and/or extend below the light-emitting diodes 16 in the stacking direction. This in particular makes it possible to increase the surface occupied by the photodetectors 18 and therefore to increase the absorbance of the incident radiation.

According to one embodiment, the device 70 comprises a layer 71 of an electrically insulating material covering the photodiodes 18 and the electrodes 14 associated with the light-emitting diodes 16 are formed on the insulating layer 71. The light-emitting diodes 16 are laterally separated by an electrically insulating layer 72 resting on the insulating layer 71. The vias 60 connecting the electrodes 14 to the transistors T1 then successively extend through the insulating layers 71, 20 and 58 and optionally through one of the photodetectors 18 and the associated electrode 15.

According to one embodiment, the interface layers 44 of the photodiodes 18 are shared and form a single interface layer 44 extending over the insulating layer 58 and comprising openings 73 for the passage of conductive vias 60 connected to the light-emitting diodes 16. The interface layer 44 can act as electrode for the photodetectors 18. As a variant, the interface layer 44 can be connected to the electrode 22 by at least one conductive via, not shown, passing through the insulating layers 71 and 72.

During operation, the photodiodes 18 essentially detect the incident light that propagates between the light-emitting diodes 16.

FIGS. 5 and 6 are top views schematically illustrating two arrangements of the light-emitting diodes 16 and photodiodes 18.

In the embodiment illustrated in FIG. 5, each photodiode 18 extends below a single light-emitting diode 16 and protrudes laterally relative to the light-emitting diode 16. The photodiode 18 can be centered on the corresponding light-emitting diode 18.

In the embodiment illustrated in FIG. 6, each photodiode 18 extends below several light-emitting diodes 16, for example four light-emitting diodes, in particular a light-emitting diode emitting blue light, a light-emitting diode emitting red light and two light-emitting diodes emitting green light.

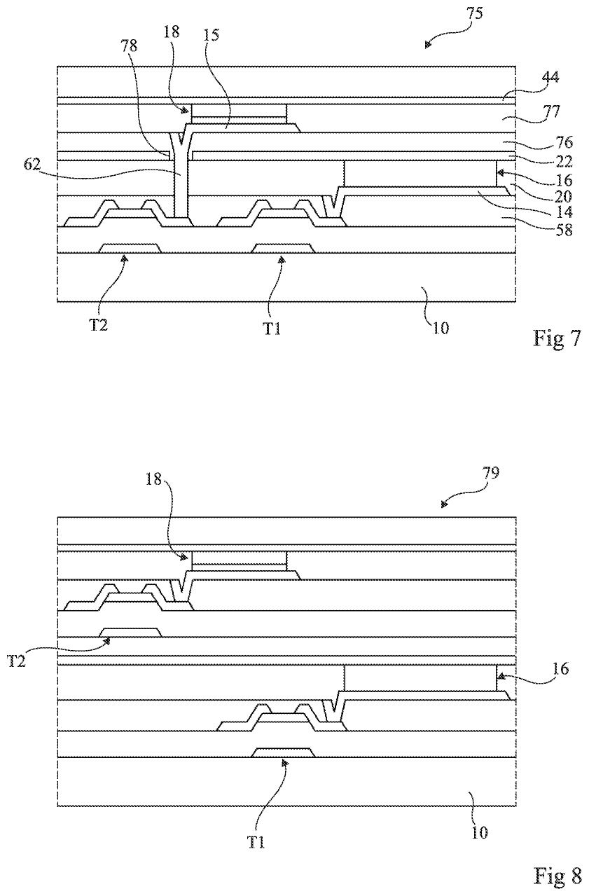

FIG. 7 is a schematic sectional view of one embodiment of an optoelectronic device 75. The device 75 comprises all of the elements of the device 70 illustrated in FIG. 4, except that the respective positions of the photodetectors 18 and the light-emitting diodes 16 are reversed, the light-emitting diodes 16 being made between the transistors T1, T2 and the photodetectors 18 in the stack of layers covering the substrate 10.

According to one embodiment, the device 75 comprises a layer 76 of an electrically insulating material covering the light-emitting diodes 16 and the electrodes 15 associated with the photodiodes 18 are formed on the insulating layer 76. The photodetectors 18 are laterally separated by an electrically insulating layer 77 resting on the insulating layer 76. The vias 62 connecting the electrodes 15 to the transistors T2 then successively extend through the insulating layers 76, 20 and 58 and optionally through one of the light-emitting diodes 16 and the associated electrode 15.

According to one embodiment, the electrode 22 comprises openings 78 for the passage of the conductive vias 62 connected to the photodetectors 18. Furthermore, according to one embodiment, the interface layers 44 of the photodiodes 18 are shared and form a single interface layer 44 extending over the insulating layer 77. The interface layer 44 can act as electrode for the photodetectors 18. As a variant, the interface layer 44 can be connected to the electrode 22 by at least one conductive via, not shown, passing through the insulating layers 76 and 77.

The present embodiment advantageously makes it possible for the formation of the photodetectors 18 to take place after the set of steps associated with the formation of the light-emitting diodes 16. Indeed, the steps associated with the formation of the light-emitting diodes 16 can comprise steps for heating to temperatures above 150° C. which may not be compatible with the materials used to produce the photodetectors 18.

FIG. 8 is a schematic sectional view of one embodiment of an optoelectronic device 79. The device 79 comprises all of the elements of the device 70 shown in FIG. 4, except that the transistors T1 and the transistors T2 are made on two different levels of the stack of layers covering the substrate 10. In the present embodiment, the transistors T1 and the light-emitting diodes 16 are formed between the substrate 10 and the transistors T2. As a variant, the transistors T2 and the photodetectors 18 can be formed between the substrate 10 and the transistors T2.

The present embodiment makes it possible, advantageously, to easily produce the active regions 54 of the transistors T1 from a different material from the active regions 54 of the transistors T2. According to one embodiment, the active regions 54 of the transistors T1 connected to the light-emitting diodes 16 can be made from LIPS, which makes it possible to obtain transistors T1 with an excellent threshold voltage stability, and the active regions 54 of the transistors T2 connected to the photodetectors 18 can be made from IGZO or from aSi, which makes it possible to obtain transistors T2 with leakage currents below 10 fA.

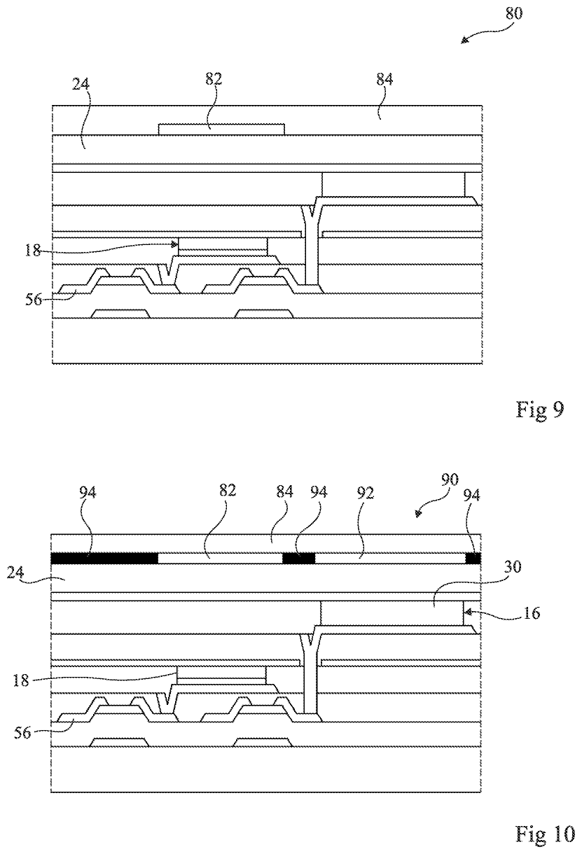

FIG. 9 is a schematic sectional view of one embodiment of an optoelectronic device 80. The optoelectronic device 80 comprises all of the elements of the optoelectronic device 70 previously described in relation with FIG. 4 and further comprises, for each photodiode 18, a color filter 82 resting on the coating 24 and aligned with the photodiode 18 along the stacking direction of the device 80. An encapsulating layer 84 is shown covering the colored filters and the coating 24. The encapsulating layer 84 is transparent or partially transparent to the visible light. The colored filters 82 can be made from colored resin or from a colored plastic material such as polydimethylsiloxane (PDMS). The colored filters 82 make it possible to filter the incident radiation that reaches each photodiode 18. This makes it possible to acquire an image preferentially in a given wavelength range, for example the green, which can be advantageous in particular when the image sensor is used to detect a fingerprint of a user.

FIG. 10 is a schematic sectional view of one embodiment of an optoelectronic device 90. The optoelectronic device 90 comprises all of the elements of the optoelectronic device 80 previously described in relation with FIG. 9 and further comprises, for each light-emitting diode 16, a color filter 92 resting on the coating 24 and aligned with the light-emitting diode 16 along the stacking direction of the device 90. A mask 94 which is opaque to the visible light can extend over the coating 24 between the colored filters 82 and 92, in particular aligned with metal tracks of the optoelectronic device 90, in particular the conductive tracks 56. In the present embodiment, the transmittance of the colored filter 92 is close to the emission spectrum of the active region 30 of the underlying light-emitting diode 16. This means that the colored filter 92 substantially completely allows the light emitted by the active region 30 of the light-emitting diode 16 to pass and blocks the other wavelengths.

The colored filters 92 and the opaque mask 94 perform an anti-reflective function. It is then not necessary to provide an antiglare coating covering the encapsulating layer 84 and for example comprising a linear polarizer and quarter-wave plate.

The radiation emitted by the active region 30 of the light-emitting diode 16 passes through the colored filter 92 covering the light-emitting component 16. The transmittance of the colored filter 92 being close to the emission spectrum of the light-emitting diode 16, the radiation emitted by the active region 30 is substantially not attenuated by the colored filter 92.

When an object is present in front of the encapsulating layer 84, the radiation is at least partially reflected by the object, not shown, for example the finger of a user. The reflected radiation is absorbed by the opaque mask 94 except at the filters 82, where the reflected radiation progresses until it reaches the photodetectors 18. Since there is no antiglare system comprising a polarizer and a quarter-wave plate, the attenuation of the reflected radiation, during its progression to the image sensor, is reduced.

The majority of the reflections perceived by a user of a conventional optoelectronic device comprising a display screen and an image sensor comes from reflections on metal tracks of the optoelectronic device. In the present embodiment, the outside radiation that reaches the encapsulating layer 84 is absorbed by the opaque mask 94 without reflecting on the metal tracks of the optoelectronic device 90 covered by the opaque mask 94. Furthermore, the outside radiation that passes through the colored filters 82 is reflected little or not at all. An antiglare function is therefore obtained. The outside radiation that reaches the colored filter 92 can in particular reflect on the electrode 14. However, given that this radiation is filtered by the colored filter 92, the intensity of the radiation reflected toward an observer is reduced.

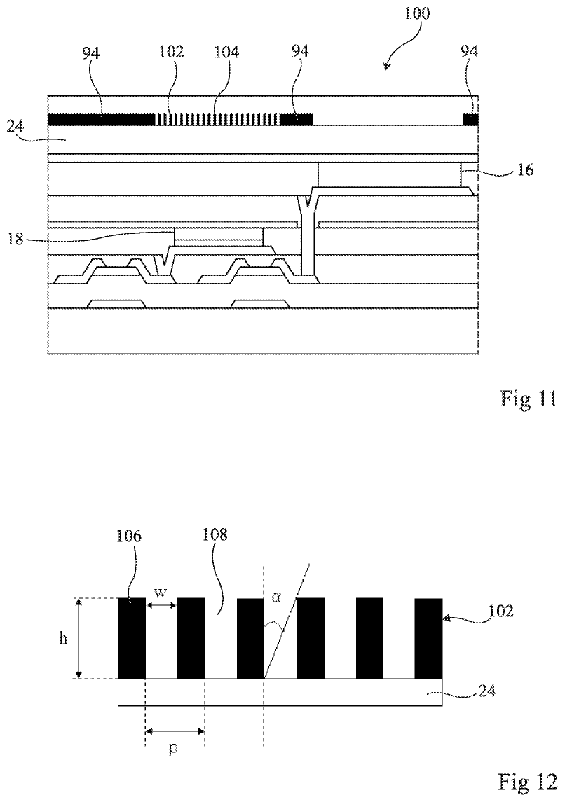

FIG. 11 is a schematic sectional view of one embodiment of an optoelectronic device 100. The optoelectronic device 100 comprises all of the elements of the optoelectronic device 90 previously described in relation with FIG. 10 except that the colored filter 92 is not present and the filter 82 is replaced by an angular filter 102.

Each angular filter 102 is suitable for filtering the incident radiation based on the incidence of the radiation relative to the upper face 104 of the angular filter 102, in particular so that each photodetector 18 receives only the rays whose incidence relative to an axis perpendicular to the upper face 104 of the angular filter 102 is less than a maximum angle of incidence of less than 45°, preferably less than 30°, more preferably less than 20°, still more preferably less than 10°. The angular filter 102 is suitable for blocking the rays of the incident radiation whose incidence relative to an axis perpendicular to the upper face 104 of the angular filter 102 is greater than the maximum angle of incidence.

According to one embodiment, for an application for the determination of fingerprints, the finger of a user is placed in contact with the upper face of the optoelectronic device such that the light rays passing through contact zones between the finger and the upper face are strongly transmitted while the light rays passing through zones which are not in contact, also called valleys, are more weakly transmitted. The photodetectors 18 which are located opposite contact zones collect the light diffused with a low incidence while the photodetectors 18 situated opposite zones which are not in contact collect little light, since this is for the most part blocked by the angular filter 102.

According to another embodiment, the optoelectronic device may comprise the colored filters 82, 92 previously described in relation with FIG. 10 and the opaque mask 94 and the angular filter 102 previously described in relation with FIG. 11 formed on two different levels in the stack of layers covering the substrate 10. According to another embodiment, the colored filters 82, 92 previously described in relation with FIG. 10 and the opaque mask 94 and the angular filter 102 previously described in relation with FIG. 11 formed on two different levels in the stack of layers covering the substrate 10, the colored filters 82, 92 being formed above or below the opaque mask 94 relative to the substrate 10.

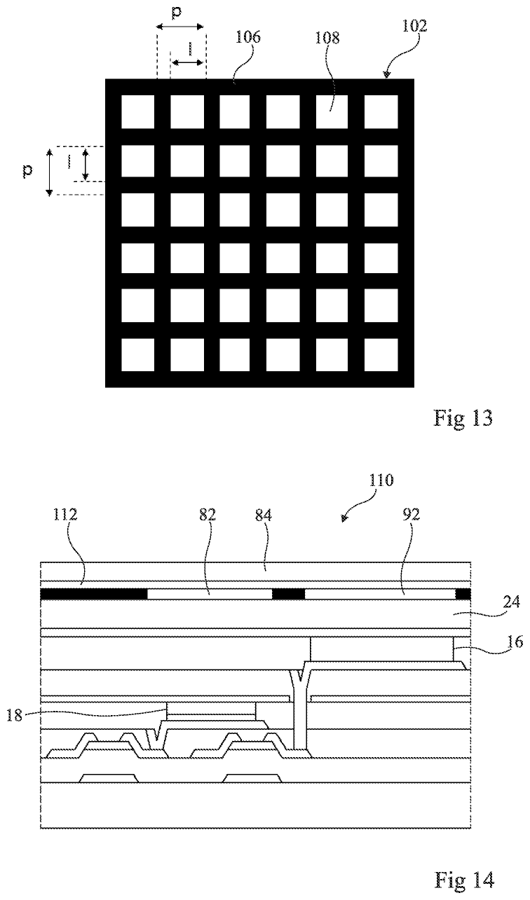

FIGS. 12 and 13 are respectively a sectional view and a top view, both of which are partial and schematic, of one embodiment of the angular filter 102.

In the present embodiment, the angular filter 102 comprises a support, formed for example by the coating 24, and walls 106 resting on the support 24 and delimiting holes 108. Reference “h” denotes the height of the walls 106 measured from the support 24. The walls 106 are opaque with respect to the radiation detected by the photodetectors 18, for example absorbent and/or reflective relative to the radiation detected by the photodetectors 18. According to one embodiment, the walls 106 are absorbent in the visible and/or the near infrared and/or the infrared. The walls 106 can be made from the same material as the opaque mask 94.

In FIG. 13, the holes 108 are shown with a square straight section. In general, the straight section of the holes 108 in top view can be circular, oval or polygonal, for example triangular, square or rectangular.

According to one embodiment, the holes 108 are positioned in rows and columns. The holes 108 can have substantially the same dimensions. Reference “w” denotes the width of a hole 108 measured along the direction of the rows or of the columns. According to one embodiment, the holes 108 are positioned evenly in rows and columns. Reference “p” denotes the repetition pitch of the holes 108, that is to say, the distance seen from above of the centers of two successive holes 64 of a row or of a column.

The angular filter 102 shown in FIGS. 12 and 13 only allows the rays of the incident light to pass whose incidence relative to the support 24 is less than a maximum angle of incidence α, which is defined by the following relationship (1):

tan α=w/h (1)

The smaller the ratio w/h is, the smaller the maximum angle of incidence α is. The transmittance at zero incidence of the angular filter 102 is proportional to the ratio between the transparent surface seen from above and the absorbent surface of the angular filter 102. For applications at a low light level, it is desirable for the transmittance to be maximal so as to increase the quantity of light collected by the image sensor. For applications at a high light level, the transmittance can be decreased so as not to blind the image sensor.

The ratio h/w can vary from 1 to 20. The pitch p can vary from 5 μm to 30 μm, for example about 20 μm. The height h can vary from 1 μm to 1 mm, preferably from 50 μm to 300 μm, for example about 100 μm. The width w can vary from 2 μm to 30 μm, for example about 10 μm.

The holes 108 can be filled with air or filled with a material which is at least partially transparent to the radiation detected by the photodetectors 18, for example polydimethylsiloxane (PDMS). As a variant, the holes 108 can be filled with a partially absorbent material so as to chromatically filter the rays which are angularly filtered by the angular filter 102. The angular filter 102 can then further play the role of the colored filter 82 previously described in relation with FIG. 9. This makes it possible to reduce the thickness of the system relative to the case where a colored filter different from the angular filter 102 is present. The partially absorbent filler material can be a colored resin or a colored plastic material such as PDMS.

The filler material of the holes 108 can be adapted so as to have a refraction index adaptation with the upper layer which is in contact with the angular filter 102 or so as to stiffen the structure and to improve the mechanical holding of the angular filter 102.

In the embodiment illustrated in FIGS. 12 and 13, the walls 106 are made entirely from an absorbent material at least for the wavelengths to be angularly filtered. The walls 106 can be made from colored resin, for example a colored or black SU-8 resin. As an example, the walls 106 can be made from a black resin which is absorbent in the visible domain and the near infrared.

One embodiment of a method for manufacturing the angular filter 102 shown in FIGS. 12 and 13 comprises the following steps:

depositing a layer of colored resin on the support 24, the thickness of which is substantially equal to the height h;

printing patterns from the walls 106 in the layer of resin by photolithography; and

developing the layer of resin so as to keep only the walls 106.

Another embodiment of a method for manufacturing the angular filter 102 shown in FIGS. 12 and 13 comprises the following steps:

forming a mold from transparent resin, through photolithography steps, having a shape complementary to the desired shape of the walls 106;

filling the mold with the material making up the walls 106; and

removing the obtained structure from the mold.

Another embodiment of a method for manufacturing the angular filter 102 shown in FIGS. 12 and 13 comprises perforating a colored film with thickness h, for example a film made from PDMS, PMMA, PEC, COP. The perforation can be done by using a microperforation tool for example comprising microneedles in order to obtain the desired dimensions of the holes 108 and pitch of the holes 108.

According to a variant, each wall 106 can comprise a core 108 made from a first material which is at least partially transparent to the radiation detected by the image sensor and covered by a layer which is opaque to the radiation detected by the photodetectors 18, for example absorbent and/or reflective relative to the radiation detected by the photodetectors 18. The first material can be a resin. The second material can be a metal, for example aluminum (Al) or chromium (Cr), a metal alloy or an organic material.

One embodiment of a method for manufacturing an angular filter according to the variant previously described comprises the following steps:

depositing a layer of transparent resin on the support, for example by spin coating or slot-die coating;

printing patterns from the walls in the layer of resin by photolithography;

developing the layer of resin so as to keep only the cores of the walls; and

forming the opaque or reflective layer on the cores, in particular by selective deposition, for example by evaporation, of the second material only on the cores, or by depositing a layer of the second material on the cores and on the support between the cores and by removal of the second material which is present on the support.

FIG. 14 is a schematic sectional view of one embodiment of an optoelectronic device 110. The optoelectronic device 110 comprises all of the elements of the optoelectronic device 90 previously described in relation with FIG. 10 and further comprises an infrared filter 112 interposed between the colored filters 82, 92 and the encapsulating layer 84. The infrared filter 112 is for example suitable for blocking the radiation whose wavelengths are between 590 nm and 1000 nm. The infrared filter 112 advantageously makes it possible to filter the contribution of the solar radiation on the image sensor.

Various embodiments have been described. Different variants and modifications will appear to those skilled in the art. Various embodiments with various variants have been described above. It will be noted that one skilled in the art may combine various elements of these various embodiments and variants without demonstrating an inventive step. In particular, the infrared filter 112 shown in FIG. 14 can be used with the optoelectronic device 80 shown in FIG. 9.

1. An optoelectronic device comprising a display screen and an image sensor, the display screen comprising a matrix of organic light-emitting components connected to first transistors, the image sensor comprising a matrix of organic photodetectors connected to second transistors, the resolution of the optoelectronic device for the light-emitting components being greater than 300 ppi and the resolution of the optoelectronic device for the photodetectors being greater than 300 ppi, the total thickness of the optoelectronic device being less than 2 mm.

2. The optoelectronic device according to claim 1, wherein the first and second transistors comprise semiconductor regions in contact with a first electrically insulating layer.

3. The optoelectronic device according to claim 2, further comprising a second electrically insulating layer, all of first electrodes being in contact with the second electrically insulating layer.

4. The optoelectronic device according to claim 3, further comprising a second electrode which is attached to all of the light-emitting components and/or to all of the photodetectors.

5. The optoelectronic device according to claim 4, wherein the second electrode is in contact with all of the light-emitting components and with all of the photodetectors.

6. The optoelectronic device according to claim 1, further comprising a substrate and a stack of layers covering the substrate and containing all of the light-emitting components and the photodetectors, wherein the photodetectors are located between the light-emitting components and the substrate or the light-emitting components are located between the photodetectors and the substrate.

7. The optoelectronic device according to claim 6, wherein the photodetectors comprise at least one electrically conductive or semiconductive layer shared by all of the photodetectors and comprising openings, the light-emitting components being connected to the first transistors by electrically conductive elements extending through the openings.

8. The optoelectronic device according to claim 4, further comprising a substrate and a stack of layers covering the substrate and containing all of the light-emitting components and the photodetectors, wherein the photodetectors are located between the light-emitting components and the substrate or the light-emitting components are located between the photodetectors and the substrate, wherein the second electrode is attached to all of the light-emitting components and comprises openings, the photodetectors being connected to the second transistors by electrically conductive elements extending through the openings.

9. The optoelectronic device according to claim 6, wherein at least one of the photodetectors covers more than one light-emitting component.

10. The optoelectronic device according to claim 6, wherein each photodetector covers a single light-emitting component.

11. The optoelectronic device according to claim 4, further comprising a substrate and a stack of layers covering the substrate and containing all of the light-emitting components and the photodetectors, wherein the photodetectors are located between the light-emitting components and the substrate or the light-emitting components are located between the photodetectors and the substrate, wherein the photodetectors comprise at least one electrically conductive or semiconductive layer shared by all of the photodetectors and comprising openings, the light-emitting components being connected to the first transistors by electrically conductive elements extending through the openings, and wherein the electrically conductive or semi-conductive layer is attached to the second electrode.

12. The optoelectronic device according to claim 1, further comprising first colored filters covering the photodetectors.

13. The optoelectronic device according to claim 12, further comprising second colored filters covering the light-emitting components.

14. The optoelectronic device according to claim 13, further comprising a layer which is opaque to the radiation detected by the photodetectors extending between the first and second filters.

15. The optoelectronic device according to claim 1, further comprising an angular filter, covering each photodetector, and which is suitable for blocking rays of said radiation whose incidence relative to a direction orthogonal to a face of the optoelectronic device is above a threshold and for allowing rays of said radiation to pass whose incidence relative to a direction orthogonal to the face is below the threshold.

16. The optoelectronic device according to claim 1, wherein each light-emitting component comprises a first active region which is the region from which the majority of the radiation emitted by the light-emitting component is emitted, and each photodetector comprises a second active region which is the region from which the majority of the radiation detected by the photodetector is detected.

17. The optoelectronic device according to claim 1, wherein the first and second transistors are field-effect transistors comprising gates, the optoelectronic device further comprising first conductive tracks attached to the gates of the first transistors and second conductive tracks attached to the gates of the second transistors and wherein at least one of the first conductive tracks is also attached to the gate of one of the second transistors.

18. The optoelectronic device according to claim 17, wherein the light-emitting components comprise at least first light-emitting components which are suitable for emitting first radiation and second light-emitting components which are suitable for emitting second radiation, and wherein the first conductive tracks attached to the gates of the first transistors connected to the first light-emitting components are also attached to the gates of the second transistors connected to the photodetectors adjacent to the first light-emitting components.

19. The optoelectronic device according to claim 1, further comprising an infrared filter covering the photodetectors.

20. The optoelectronic device according to claim 1, wherein the optoelectronic device is used for detecting at least one fingerprint of a user.
